(19) United States
(12) Patent Application Publication
(10) Pub. No.: US 2024/0213181 A1
(43) Pub. Date: Jun. 27, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Hao SUN, Beijing (CN); Xiaoxia HUANG, Beijing (CN); Enjian YANG, Beijing (CN); Liang GAO, Beijing (CN); Shuang ZHANG, Beijing (CN); Feifan LI, Beijing (CN); Bin WANG, Beijing (CN); Hufei YANG, Beijing (CN); Ajuan DU, Beijing (CN); Yongle WANG, Beijing (CN)

(21) Appl. No.: 17/914,235

(22) PCT Filed: Nov. 15, 2021
(86) PCT No.: PCT/CN2021/130597

§ 371 Date: Sep. 23, 2022

(30) Foreign Application Priority Data
Feb. 3, 2021 (CN) 202110151117.X

(51) Int. Cl. H01L 23/00; H01L 23/498; H01L 23/552; H01L 23/60; H05K 1/02; H05K 1/18

(52) U.S. Cl. CPC H01L 23/564; H01L 23/60; H05K 1/0268; H01L 23/4985; H01L 23/552; H05K 1/18; H05K 2201/10128

(57) ABSTRACT

Provided is a display panel, including: a substrate, the substrate comprising a display area and a non-display area, the non-display area comprising a bonding area located at a side of the display area, the bonding area comprising a plurality of bonding pads, wherein the display panel further comprises a first insulating protective film layer, a detection pad is provided between at least two of the plurality of bonding pads, and the first insulating protective film layer is located at a side of the detection pad away from the substrate. A display device is further provided.

### CROSS-REFERENCE TO RELATED APPLICATIONS

The present application claims priority to Chinese Patent Application No. 202110151117.X filed in China on Feb. 3, 2021, the disclosure of which is hereby incorporated by reference in its entirety.

### TECHNICAL FIELD

The present disclosure relates to the technical field of manufacturing display product, and in particular, to a display panel and a display device.

### BACKGROUND

The flexible OLED module needs to be subjected to an aging treatment in a cell state, and needs to be lighted up for a long time to stabilize the performance of the light-emitting device. ET Pad (Electric Test Pad) is the connection Pin for the lighting up in the cell state. For a product having a small size, the ET Pad is arranged at the lower end of a bonding pin for the panel and the Chip on Film (COF), and will be cut off by laser before the panel is bonded to the COF and thus will not be left on the product. In order to avoid a corrosion at the cross-section of the metal trace in the cut SD layer, the trace in the gate layer which is not easily subject to a corrosion is used for the cutting region, but the resistance of the gate layer is about 10 times that of the SD trace. For a product having a large size, the current generated when being lighted up for the aging is more than twice that of the product having a small size. The large current may result in a burning to the trace in the gate layer when performing the aging, which may lead to an aging failure. Therefore, the ET Pad for the product having a large size needs to be placed on both sides of the bonding pin for the panel and the FPC or COF, but the ET Pad will be left on the product, and a corrosion may occur in an environment of high temperature and high humidity.

### SUMMARY

To address the above technical issue, the present disclosure provides a display panel and a display device, which can effectively prevent ET Pads from being corroded.

To achieve this, embodiments of the present disclosure provide the following technical solution. A display panel, including: a substrate, wherein the substrate includes a display area and a non-display area, the non-display area includes a bonding area located at a side of the display area, the bonding area including a plurality of bonding pads, wherein the display panel further includes a first insulating protective film layer, a detection pad is provided between at least two of the plurality of bonding pads, and the first insulating protective film layer is located at a side of the detection pad away from the substrate.

Optionally, the display panel further includes a Chip on Film, connected to the bonding pads, wherein the display panel further includes a second insulating protective film layer located at a side of the Chip on Film away from the substrate.

Optionally, the first insulating protective film layer and the second insulating protective film layer are provided as one-piece structure.

Optionally, the first insulating protective film layer and the second insulating protective film layer are separately provided in a first direction, the first direction is a direction from the bonding pads towards the detection pad.

Optionally, the display panel further includes a circuit board, wherein the Chip on Film is connected to the circuit board by bonding, and the display panel further includes a third insulating protective film layer located at a side of the circuit board away from the substrate.

Optionally, the circuit board is provided with at least one connector for a connection to an external device, and the third insulating protective film layer includes at least two sub-insulating protective film layers, and two adjacent sub-insulating protective film layers are separated by a connector in the at least one connector.

Optionally, the third insulating protective film layer includes at least two sub-insulating protective film layers in a second direction, a sub-insulating protective film layer adjacent to the second insulating protective film layer and the second insulating protective film layer are provided as one-piece structure, the second direction is a direction from the Chip on Film towards the circuit board.

Optionally, the first insulating protective film layer, the second insulating protective film layer, and the third insulating protective film layer are all made of insulating tape.

Optionally, the display panel further includes a first conductive film layer for discharging static electricity, wherein the first conductive film layer is located at a side of the second insulating protective film layer away from the substrate.

Optionally, the display panel further includes a second conductive film layer for discharging static electricity, wherein the second conductive film layer is located at a side of the third insulating protective film layer away from the substrate, and the third insulating protective film layer is provided with an opening for connecting the second conductive film layer to the ground.

Optionally, the first conductive film layer and the second conductive film layer are provided as one-piece structure.

Optionally, the first conductive film layer and the second conductive film layer are provided as one-piece structure by using a conductive fabric.

Optionally, the display panel further includes a wave-absorbing film layer for absorbing an electromagnetic wave, wherein the circuit board is provided with an electronic component, the third insulating protective film layer includes a first region located at a side of the electronic component away from the substrate, and the wave-absorbing film layer is located between the first region and the second conductive film layer.

In a direction perpendicular to the circuit board, an orthographic projection of the wave-absorbing film layer is fully located within the circuit board, and the orthographic projection of the wave-absorbing film layer onto the circuit board is larger than an orthographic projection of the electronic component onto the circuit board.

An embodiment of the present disclosure further provides a display device, including the display panel as described above.

The present disclosure has an advantageous effect that the detection pad is protected from being corroded by the provision of the first insulating protective film layer.

### BRIEF DESCRIPTION OF THE DRAWINGS

FIG. 1 shows a schematic diagram of a display panel without any protective films in an embodiment of the present disclosure;

FIG. 2 shows a first schematic diagram illustrating a structure of a display panel in an embodiment of the present disclosure;

FIG. 3 shows a second schematic diagram illustrating a structure of a display panel in an embodiment of the present disclosure; and

FIG. 4 shows a third schematic diagram illustrating a structure of a display panel in an embodiment of the present disclosure.

### DETAILED DESCRIPTION

To make the object, the technical solution and advantage of the embodiments of the present disclosure clear, a detailed description for embodiments of the present disclosure will be given in conjunction with appended drawings. It is to be understood that the described embodiments are some, but not all, of the embodiments of the disclosure. Based on the described embodiments of the present disclosure, all other embodiments that would be conceived by one of ordinary skill in the art fall within the scope of the present disclosure.

In describing the present disclosure, it should be noted that the terms “central”, “upper”, “lower”, “left”, “right”, “vertical”, “horizontal”, “inner”, “outer”, and the like indicate an orientation or positional relationship based on the orientation or positional relationship shown in the figures, which are merely used to facilitate the description of the present disclosure and simplify the description, and do not indicate or imply that the referenced device or element must have the particular orientation, be constructed and operated in the particular orientation, and thus should not be construed as limiting the present disclosure. Furthermore, the terms “first”, “second”, and “third” are only used for the purpose of illustration, and are not construed as indicating or implying relative importance.

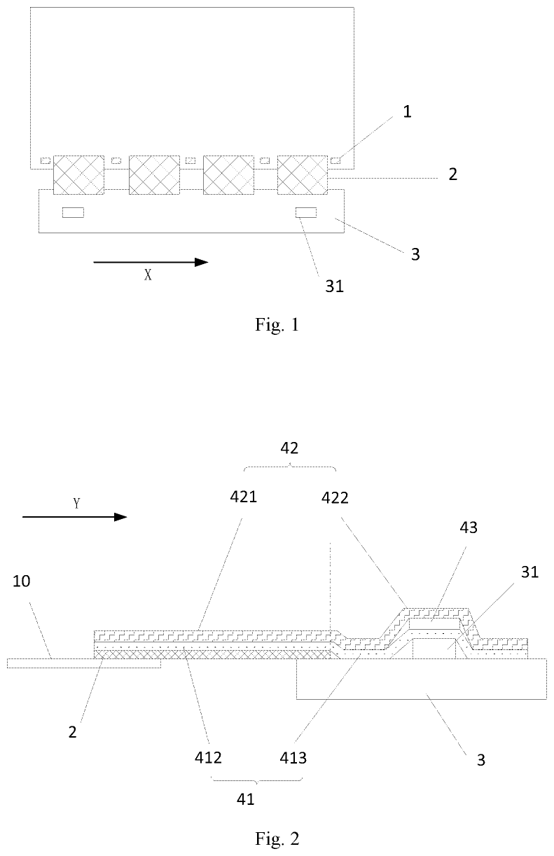

As shown in FIGS. 1 to 4, in an embodiment, a display panel is provided, the display panel includes a substrate including a display area and a non-display area 10 surrounding the display area. The non-display area 10 includes a bonding area located at a side of the display area, the bonding area includes a plurality of bonding pads. The display panel further includes a first insulating protective film layer 411, a detection pad 1 is provided between at least two of the plurality of bonding pads, and the first insulating protective film layer 411 is located at a side of the detection pad 1 away from the substrate.

The detection pad 1 is effectively protected from being corroded by providing the first insulating protective film layer 411.

Illustratively, in the embodiment, the display panel further includes a Chip on Film 2, connected to the bonding pads. The display panel further includes a second insulating protective film layer 412 located at a side of the Chip on Film 2 away from the substrate.

The Chip on Film 2 can be protected with the provision of the second insulating protective film layer 412.

Illustratively, in the embodiment, the first insulating protective film layer 411 and the second insulating protective film layer 412 are integrally formed as one-piece structure. This can simplify process steps involved in manufacturing process.

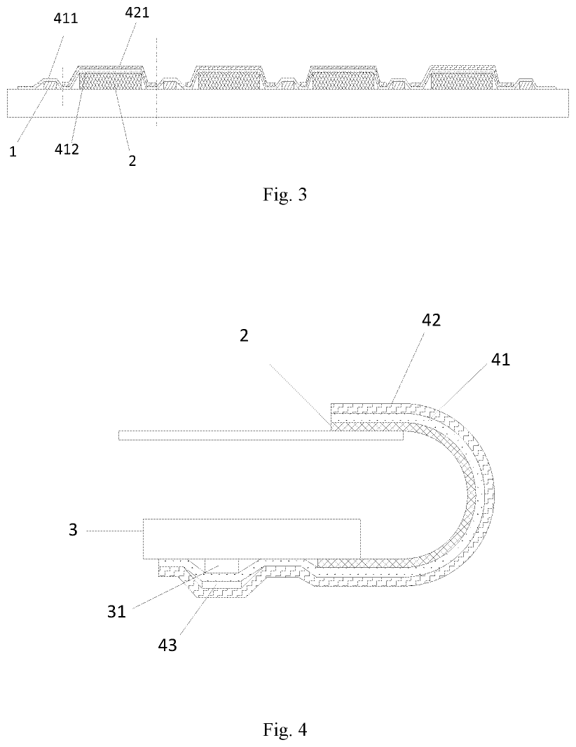

Illustratively, in the embodiment, the first insulating protective film layer 411 and the second insulating protective film layer 412 are separately provided in a first direction (an X direction in FIG. 1), the first direction is a direction from the bonding pads to the detection pad 1. Referring to FIG. 3, the first insulating protective film layer 411 and the second insulating protective film layer 412 are separated at positions indicated by the dotted line.

By providing the first insulating protective film layer 411 and the second insulating protective film layer 412 separately in the first direction, the first insulating protective film layer 411 and the second insulating protective film layer 412 can be flexibly provided according to requirements.

Illustratively, in the embodiment, the display panel further includes a circuit board 3, the Chip on Film 2 is connected to the circuit board 3 by bonding, and the display panel further includes a third insulating protective film layer 413 located at a side of the circuit board 3 away from the substrate.

FIG. 2 shows the display panel is in an unbent state, and FIG. 4 shows the display panel is in a bent state. A face of the substrate where the bonding pads are provided is a front face, and a face of the substrate opposite to the front face is a back face. When the display panel is in the unbent state, the third insulating protective film layer 413 is located at a side away from the front face of the substrate. When the display panel is in the bent state, the circuit board 3 is located at the back face of the substrate, and the third insulating protective film layer 413 is located at a side away from the back face of the substrate.

Illustratively, in the embodiment, the third insulating protective film layer 413 and the second insulating protective film layer 412 are integrally formed as one-piece structure. That is to say, by providing the first insulating protective film layer 411, the second insulating protective film layer 412 and the third insulating protective film layer 413 integrally as one-piece structure, the protection for the detection pad 1, the Chip on Film 2 and the circuit board 3 can be done in a single attaching process, which is simple and easy to operate. In addition, when manufacturing the insulating protective film layers, the first insulating protective film layer 411, the second insulating protective film layer 412 and the third insulating protective film layer 413 are integrally formed as one-piece structure, the production efficiency can thereby be improved. However, in practical application, the circuit board 3 is provided with at least one connector for a connection to an external device (e.g. a host), and the connector cannot be covered by the third insulating protective film layer 413. Therefore, in order to avoid interference, the third insulating protective film layer 413 includes at least two sub-insulating protective film layers, and two adjacent sub-insulating protective film layers are separated by the connector.

The layer number of the sub-insulating protective film layers is determined according to the quantity of the connectors. For example, if two connectors are provided on the circuit board 3, then the third insulating protective film 413 includes three sub-insulating protective film layers, and two adjacent sub-insulating protective film layers are separated by a corresponding connector in the two connectors.

Illustratively, in the embodiment, the third insulating protective film layer 413 includes at least two sub-insulating protective film layers in a second direction, among which, a sub-insulating protective film layer adjacent to the second insulating protective film layer 412 and the second insulating protective film layer 412 are formed as one-piece structure, the second direction is a direction from the Chip on Film 2 to the circuit board 3, referring to a Y direction in FIG. 2.

In practical application, the circuit board 3 further includes a connection element connected to an element such as a touch control structure (namely, a connector to be connected to an element external to the circuit board 3), and in the embodiment, for example, the sub-insulating protective film layer is further provided with an opening for avoiding such element.

In the embodiment, the first insulating protective film layer 411, the second insulating protective film layer 412, and the third insulating protective film layer 413 are all made of insulating tape, but the present disclosure is not limited thereto.

For products with COF (Chip on Film 2), there is a risk of ESD (static electricity) in the bonding area between the COF and the panel; in addition, the circuit in the bending area of COF may cause an electromagnetic interference to the whole machine.

Illustratively, in the embodiment, the display panel further includes a first conductive film layer 421 for discharging the static electricity, wherein the first conductive film layer 421 is located at a side of the second insulating protective film layer 412 away from the substrate.

The provision of the first conductive film layer 421 can increase an electrostatic protection for the Chip on Film 2, and also function as an electromagnetic protection for the bending region of the Chip on Film 2.

Illustratively, in the embodiment, the display panel further includes a second conductive film layer 422 for discharging the static electricity, wherein the second conductive film layer 422 is located at a side of the third insulating protective film layer 413 away from the substrate, and an opening is provided in the third insulating protective film layer 413 so that the second conductive film layer is connected to the ground.

The second conductive film layer 422 is connected to the ground on the circuit board 3 through the opening in the third insulating protective film layer 413 to discharge the static electricity, the static electricity can be prevented from occurring on the circuit board 3.

Illustratively, in the embodiment, the first conductive film layer 421 and the second conductive film layer 422 are integrally provided as one-piece structure.

In the embodiment, the first conductive film layer 421 and the second conductive film layer 422 are integrally formed as the one-piece structure by using a conductive fabric, but the present disclosure is not limited thereto.

By forming the first conductive film layer 421 and the second conductive film layer 422 integrally, the processing steps in the manufacturing process can be simplified. By attaching the one-piece structure including the first conductive film layer 421 and the second conductive film layer 422 to the one-piece structure including the first insulating protective film layer 411, the second insulating protective film layer 412 and the third insulating protective film layer 413, the resultant attached structure which is an integral structure is then attached to a corresponding region of the display panel, which is simple and easy to operate.

Illustratively, in the embodiment, the display panel further includes a wave-absorbing film layer 43 for absorbing an electromagnetic wave, wherein the circuit board 3 is provided with an electronic component 31, the third insulating protective film layer 413 includes a first region located at a side of the electronic component 31 away from the substrate, and the wave-absorbing film layer 43 is located between the first region and the second conductive film layer 422.

The product having a large size may have a large number of electronic components 31 including ICs on the PCB, which will generate a large amount of electromagnetic noise wave during operation, and lead to a radio frequency interference to the whole machine. By providing the wave-absorbing film layer 43, the noise waves generated by the electronic component 31 on the circuit board 3 during operation can be absorbed efficiently, and thus the radio frequency interference to the whole machine generated by the components during operation can be reduced. In addition, the wave-absorbing film layer 43 is provided between the third insulating protective film layer 413 and the second conductive film layer 422, so that a powder falling phenomenon for the wave-absorbing material can be effectively prevented.

Illustratively, in the embodiment, in a direction perpendicular to the circuit board 3, an orthographic projection of the wave-absorbing film layer 43 onto the circuit board 3 fully falls within the circuit board 3, and the orthographic projection of the wave-absorbing film layer 43 onto the circuit board 3 is larger than an orthographic projection of the electronic component 31 onto the circuit board 3. The noise wave generated by the electronic component 31 on the circuit board 3 during its operation can be efficiently absorbed.

In the embodiment, the first insulating protective film layer 411, the second insulating protective film layer 412 and the third insulating protective film layer 413 are collectively named as an insulating layer, and the first conductive film layer 421 and the second conductive film layer 422 are in one-piece structure (collectively named as a conductive layer 42). In practical application, the insulating layer, the wave-absorbing film layer 43 and the conductive layer are attached to form one-piece structure, and then the insulating layer, the wave-absorbing film layer 43 and the conductive layer that have been attached together are integrally attached to a corresponding region of the display panel.

FIG. 2 shows a schematic diagram for a state of the Chip on Film before being bent, and FIG. 4 shows a schematic diagram for a state of the Chip on Film after being bent. After the Chip on Film 2 is bent, the circuit board 3 is located at the backlight side of the display panel. For the convenience of operation, in the embodiment, the insulating layer, the wave-absorbing film layer 43 and the conductive layer that have been attached together are attached to the display panel before the Chip on Film 2 is bent.

Specifically, in the embodiment, the display panel includes a protective film, and the protective film includes an insulating layer 41, a wave-absorbing film layer 43 and a conductive layer 42 which are sequentially arranged in a stack.

The insulating layer 41 is made of insulating tape, and includes a first insulating protective film layer 411, a second insulating protective film layer 412 and a third insulating protective film layer 413, wherein the first insulating protective film layer 411 is attached to a detection area of the display panel, the second insulating protective film layer 412 is attached to the Chip on Film 2 of the display panel, and the third insulating protective film layer 413 is attached to a circuit board 3 of the display panel.

The conductive layer 42 is made of a conductive fabric, and includes a first conductive film layer 421 and a second conductive film layer 422, wherein the first conductive film layer 421 is configured to be attached to a side of the second insulating protective film layer 412 away from the Chip on Film 2, and the second conductive film layer 422 is configured to be attached to a side of the third insulating protective film layer 413 away from the circuit board 3.

The circuit board 3 includes an electronic component 31, the third insulating protective film layer 413 includes a first region locate over the electronic component 31, and the wave-absorbing film layer 43 is located between the first region and the second conductive film layer 422.

An embodiment of the present disclosure further provides a display device, including the display panel as described above.

The display device may be any product or component with a display function, such as a liquid crystal television, a liquid crystal display, a digital photo frame, a mobile phone, a tablet computer. The display device further includes a flexible circuit board 3, a printed circuit board 3 and a back plate.

While the foregoing is directed to specific embodiments of the present disclosure, it will be understood by those skilled in the art that various modifications and adaptations may be made without departing from the principles of the disclosure, and such modifications and adaptations fall within the scope of the disclosure.

1. A display panel, comprising: a substrate, the substrate comprising a display area and a non-display area, the non-display area comprising a bonding area located at a side of the display area, the bonding area comprising a plurality of bonding pads, wherein the display panel further comprises a first insulating protective film layer, a detection pad is provided between at least two of the plurality of bonding pads, and the first insulating protective film layer is located at a side of the detection pad away from the substrate.

2. The display panel according to claim 1, further comprising: a Chip on Film, connected to the plurality of bonding pads, wherein the display panel further comprises a second insulating protective film layer located at a side of the Chip on Film away from the substrate.

3. The display panel according to claim 2, wherein the first insulating protective film layer and the second insulating protective film layer are provided as one-piece structure.

4. The display panel according to claim 2, wherein the first insulating protective film layer and the second insulating protective film layer are separately provided in a first direction, the first direction is a direction from the plurality of bonding pads towards the detection pad.

5. The display panel according to claim 3, further comprising: a circuit board, wherein the Chip on Film is connected to the circuit board by bonding, and the display panel further comprises a third insulating protective film layer located at a side of the circuit board away from the substrate.

6. The display panel according to claim 5, wherein the circuit board is provided with at least one connector for a connection to an external device, and the third insulating protective film layer comprises at least two sub-insulating protective film layers, and two adjacent sub-insulating protective film layers from the at least two sub-insulating protective film layers are separated by a connector of the at least one connector.

7. The display panel according to claim 6, wherein the third insulating protective film layer comprises at least two sub-insulating protective film layers in a second direction, a sub-insulating protective film layer adjacent to the second insulating protective film layer and the second insulating protective film layer are provided as one-piece structure, the second direction is a direction from the Chip on Film towards the circuit board.

8. The display panel according to claim 5, wherein the first insulating protective film layer, the second insulating protective film layer, and the third insulating protective film layer are all made of an insulating tape.

9. The display panel according to claim 5, further comprising: a first conductive film layer for discharging static electricity, wherein the first conductive film layer is located at a side of the second insulating protective film layer away from the substrate.

10. The display panel according to claim 9, further comprising: a second conductive film layer for discharging static electricity, wherein the second conductive film layer is located at a side of the third insulating protective film layer away from the substrate, and the third insulating protective film layer is provided with an opening for connecting the second conductive film layer to the ground.

11. The display panel according to claim 10, wherein the first conductive film layer and the second conductive film layer are provided as one-piece structure.

12. The display panel according to claim 11, wherein the first conductive film layer and the second conductive film layer are integrally provided as one-piece structure by using a conductive fabric.

13. The display panel according to claim 11, further comprising: a wave-absorbing film layer for absorbing an electromagnetic wave, wherein the circuit board is provided with an electronic component, the third insulating protective film layer comprises a first region located at a side of the electronic component away from the substrate, and the wave-absorbing film layer is located between the first region and the second conductive film layer.

14. The display panel according to claim 13, wherein in a direction perpendicular to the circuit board, an orthographic projection of the wave-absorbing film layer is fully located within the circuit board, and the orthographic projection of the wave-absorbing film layer onto the circuit board is larger than an orthographic projection of the electronic component onto the circuit board.

15. The display panel according to claim 4, further comprising: a circuit board, wherein the Chip on Film is connected to the circuit board by bonding, and the display panel further comprises a third insulating protective film layer located at a side of the circuit board away from the substrate.

16. A display device, comprising: a display panel, wherein the display panel comprises a substrate, the substrate comprising a display area and a non-display area, the non-display area comprising a bonding area located at a side of the display area, the bonding area comprising a plurality of bonding pads, wherein the display panel further comprises a first insulating protective film layer, a detection pad is provided between at least two of the plurality of bonding pads, and the first insulating protective film layer is located at a side of the detection pad away from the substrate.

17. The display device according to claim 16, further comprising: a Chip on Film, connected to the plurality of bonding pads, wherein the display panel further comprises a second insulating protective film layer located at a side of the Chip on Film away from the substrate.

18. The display device according to claim 17, wherein the first insulating protective film layer and the second insulating protective film layer are provided as one-piece structure.

19. The display device according to claim 17, wherein the first insulating protective film layer and the second insulating protective film layer are separately provided in a first direction, the first direction is a direction from the plurality of bonding pads towards the detection pad.

20. The display device according to claim 18, further comprising: a circuit board, wherein the Chip on Film is connected to the circuit board by bonding, and the display panel further comprises a third insulating protective film layer located at a side of the circuit board away from the substrate.
